(19) United States
(12) Patent Application Publication
(10) Pub. No.: US 2011/0042735 A1
(43) Pub. Date: Feb. 24, 2011

(54) SEMICONDUCTOR STORAGE DEVICE AND MANUFACTURING METHOD OF SEMICONDUCTOR STORAGE DEVICE

(75) Inventor: Hirokazu ISHIGAKI, Kanagawa (JP)

Correspondence Address: FOLEY AND LARDNER LLP;SUITE 500, 3000 K STREET NW, WASHINGTON, DC, 20007, US

(73) Assignee: Renesas Electronics Corporation

(21) Appl. No.: 12/915,894

(22) Filed: Oct. 29, 2010

(30) Foreign Application Priority Data
May 11, 2009 (JP) 2009-253923

(51) Int. Cl. H01L 29/78; H01L 21/336

(52) U.S. Cl. 257/314; 438/585; 257/E29.255; 257/E21.409

(57) ABSTRACT

A semiconductor storage device in accordance with an exemplary aspect of the present invention includes a state storage element and a transistor. In the state storage element, a first conductive region, a first insulating film, and a first electrode are successively formed on a semiconductor substrate. Further, a second insulating film and a second electrode are successively formed on the semiconductor substrate. The transistor includes the first conductive region, a second conductive region, a second insulating film, and a second electrode. The second insulating film and the second electrode are successively formed between the first and second conductive regions on the semiconductor substrate. The withstand voltage against dielectric breakdown of the first insulating film is lower than that of the second insulating film.

### INCORPORATION BY REFERENCE

This application is based upon and claims the benefit of priority from Japanese patent application No. 2009-253923, filed on Nov. 5, 2009, the disclosure of which is incorporated herein in its entirety by reference.

### BACKGROUND

1. Field of the Invention

The present invention relates to a semiconductor storage device and a manufacturing method of a semiconductor storage device. In particular, the present invention relates to a semiconductor storage device capable of being written only once and a manufacturing method of such a semiconductor storage device.

2. Description of Related Art

OTP (One Time Programable) memories have been known as a writable semiconductor storage device. The OTP memories are semiconductor storage devices capable of being written only once. Since the OTP memories have a simpler circuit configuration in comparison to flash-type memories, it is relatively easy to increase the data recording density. Therefore, the OTP memories have been expected as means to realize inexpensive large-capacity semiconductor storage devices.

Published Japanese Translation of PCT International Publication for Patent Application, No. 2005-504434 proposes a memory cell in which one-time writing is carried out by the dielectric breakdown of the gate insulating film. FIG. 11 is a cross section showing a configuration of a memory cell disclosed in Published Japanese Translation of PCT International Publication for Patent Application, No. 2005-504434. In this memory cell, transistors 110a and 110b as well as half transistors 111a and 111b are formed on a p-well active region 101. In the p-well active region 101, n⁺ regions 102a to 102c and element isolations 103 are formed. The element isolation 103 is formed, for example, by filling a trench with insulating material. Further, electrodes 105a, 105b, 106a and 106b are formed on its surface with a gate oxide film 104 interposed therebetween. The electrode 105a is connected to a terminal V_{R2}. The electrode 105b is connected to a terminal V_{R1}. The electrodes 106a and 106b are connected to a terminal V_{C1}. Further, a terminal V_{S1} is connected to the n⁺ region 102b located between the transistors 110a and 110b.

In this memory cell, the terminals V_{C1}, V_{R2} and V_{S1} are connected to, for example, a bit line, a word line, and a supply line respectively. When data is to be written into this memory cell, V_{R2} and V_{C1} are brought into a selected state while V_{S1} is brought to a ground potential. In this process, if the selected state is at a sufficiently high voltage, dielectric breakdown occurs in the part of the gate oxide film 104 located between the electrode 106a and the n⁺ region 102a. As a result, the terminals V_{S1}, V_{R2} and V_{C1} can function as one transistor.

When data is to be read from the memory cell, the terminals V_{C1}, V_{R2} and V_{S1} are used as a drain, a gate, and a source respectively. The terminal V_{S1}, which serves as the source, is brought to a ground potential and the terminal V_{R2}, which serves as the gate, is brought to a High-level potential. Further, the terminal V_{C1}, which serves as the drain, is brought to a potential lower than the High-level potential. Then, a current that flows from the source to the drain is monitored.

In this state, if the gate oxide film 104 has been dielectrically broken down and thus in a conductive state, a current flows therethrough and it is recognized as a written state. On the other hand, if the gate oxide film 104 has not been dielectrically broken down, no current flows and it is recognized as a non-written state. In this way, the memory cell shown in FIG. 11 functions as a semiconductor storage device capable of being written only once.

Further, FIG. 12 is a cross section showing a configuration of an anti-fuse transistor disclosed in Published Japanese Translation of PCT International Publication for Patent Application, No. 2007-536744. In this anti-fuse transistor, n⁺-type diffusion regions 202 and 203 are formed in a part of a substrate 201 as shown in FIG. 12. The substrate 201 is composed of, for example, p-type silicon. Further, LDD (Lightly Doped Drain) regions 204 and 205 extend from the diffusion regions 202 and 203 respectively. A variable-thickness gate oxide 206 is formed on the part of the substrate 201 located between the diffusion regions 202 and 203. The variable-thickness gate oxide 206 is formed in such a manner that its thickness on the diffusion region 203 side is thinner than the original thickness of the gate oxide. A polysilicon gate 207 is formed on the variable-thickness gate oxide 206. Further, a side-wall spacer(s) 208 is formed on the side of the variable-thickness gate oxide 206 and the polysilicon gate 207.

To write data into this anti-fuse transistor, a voltage is applied between, for example, the polysilicon gate 207 and the diffusion region 203. Then, since the thickness of the variable-thickness gate oxide 206 is thinner on the diffusion region 203 side, dielectric breakdown can be caused by a lower voltage than the voltage that would be required to cause dielectric breakdown for the original gate oxide. In this way, the writing voltage can be lowered.

FIGS. 13A to 13F are cross sections showing a typical manufacturing process of an anti-fuse transistor disclosed in Published Japanese Translation of PCT International Publication for Patent Application, No. 2007-536744. Firstly, as shown in FIG. 13A, a gate oxide 206a is formed on a substrate 201. The substrate 201 is composed of, for example, p-type silicon. After that, a resist 209 is formed by photolithography. Next, as shown in FIG. 13B, the gate oxide 206a is etched by dry-etching such as RIE. After that, the resist 209 is removed. Next, as shown in FIG. 13C, a gate oxide 206b is formed so as to cover the substrate 201 and the gate oxide 206a.

Next, as shown in FIG. 13D, a resist 210 is formed by photolithography. The resist 210 is used as an etching mask to form the variable-thickness gate oxide 206 by etching. In this stage, ideally, it is desirable that the end portion of the gate oxide 206a and the end portion of the resist 210 are aligned without causing any deviation. However, there is a limit to the alignment accuracy of an exposure device used in the photolithography. Therefore, it is necessary to design the layout while taking the deviation in the alignment into consideration. Therefore, when the width of the variable-thickness gate oxide 206a is represented by L₀ and the alignment accuracy of the photography is represented by 1ΔL, the region L at which the gate oxide 206 is disposed in design should be L=L₀+2ΔL.

Next, as shown in FIG. 13E, a variable-thickness gate oxide 206 is formed by wet-etching. After the resist 210 is removed, a polysilicon layer (not shown) is formed so as to cover the substrate 201 and the variable-thickness gate oxide 206. After that, a polysilicon gate 207 is formed by photolithography and etching. Next, as shown in FIG. 13F, LLD regions 204 and 205 are formed by impurity implanting. Next, a resist mask (not shown) is formed by photolithography. By using this resist mask, diffusion regions 202 and 203 are formed by ion implantation. Finally, a side-wall spacer(s) 208 is formed and an anti-fuse transistor shown in FIG. 12 is thereby manufactured. SUMMARY

### SUMMARY

The present inventors have found a following problem. To write data into the memory cell disclosed in Published Japanese Translation of PCT International Publication for Patent Application, No. 2005-504434 and shown in FIG. 11, it is necessary to apply a higher writing voltage than the voltage that is applied when data is read. Therefore, it is necessary to provide an additional charge-pump and a power supply to supply the writing voltage, thus increasing the costs. Further, since the writing voltage is also applied to the peripheral circuit(s) located outside the memory area, it is also disadvantageous in terms of reliability. Furthermore, in general, a device in which a high voltage is used occupies a large area in a semiconductor device, thus leading to an increase in manufacturing costs.

In order to solve the problem like this, Published Japanese Translation of PCT International Publication for Patent Application, No. 2007-536744 proposes an anti-fuse transistor to lower the writing voltage (see FIG. 12). However, to manufacture this anti-fuse transistor, it is necessary to go through the additional manufacturing process in which the thickness of the variable-thickness gate oxide 206 is processed into two levels. Therefore, the semiconductor storage device disclosed in Published Japanese Translation of PCT International Publication for Patent Application, No. 2007-536744 has a problem that increasing the packing density is difficult. In other words, as explained with reference to FIG. 13D, it is desirable that the end portions of the gate oxide 206a and the resist 210 are aligned with each other without causing any deviation in the anti-fuse transistor disclosed in Published Japanese Translation of PCT International Publication for Patent Application, No. 2007-536744. Therefore, it is necessary to take the redundancy corresponding to the alignment accuracy into consideration when the layout is designed. This matter becomes an obstacle when the interval of cell placement is to be narrowed, thus making the increase in the packing density very difficult.

Further, in order to avoid the deterioration of transistor characteristics as a result of damage caused on the substrate or the like, it is necessary to use wet-etching for the formation of the variable-thickness gate oxide 206. However, since the wet-etching is isotropic etching, the variable-thickness gate oxide 206 is etched not only in the depth direction but also in the horizontal direction. Therefore, it is necessary to take the reduction in the size of the variable-thickness gate oxide 206 caused by the etching in the horizontal direction into consideration. Accordingly, the redundancy needs to be considered even further in the layout design, thus making the anti-fuse transistor more disadvantageous for the increase in the packing density.

That is, it is very difficult to satisfy both the reduction in the writing voltage and the increase in the packing density by the above-described configuration of the anti-fuse transistor and/or its manufacturing method.

A first exemplary aspect of the present invention is a semiconductor storage device including: a state storage element; and a transistor, in which the state storage element includes: a semiconductor substrate; a first conductive region formed on the semiconductor substrate; a first insulating film formed at least above the first conductive region; a second insulating film formed on the semiconductor substrate; and a first electrode formed at least above the first insulating film, and a transistor includes: the first conductive region formed on the semiconductor substrate, the first conductive region extending from the state storage element; a second conductive region formed on the semiconductor substrate, the second conductive region being spaced apart from the first conductive region; a second insulating film formed between the first and second conducting regions on the semiconductor substrate, the second insulating film being in common with the state storage element; and a second electrode formed at least above the second insulating film, and the first insulating film has a lower withstand voltage against dielectric breakdown than that of the second insulating film.

In the semiconductor storage device in accordance with the first aspect of the present invention, the first insulating film has a lower withstand voltage against dielectric breakdown than that of the second insulating film, which is the gate insulating film of the transistor. Therefore, it is possible to dielectrically break down the first insulating film by a lower writing voltage in order to record data in the state storage element.

A second exemplary aspect of the present invention is a method of manufacturing a semiconductor storage device in which a state storage element that records data and a transistor that reads out data recorded in the state storage element are integrated on a semiconductor substrate, the manufacturing method including: forming a second insulating film on a region of the semiconductor substrate at which the transistor is disposed and a region of the semiconductor substrate at which the state storage element is disposed; forming a first conductive region extending from the state storage element to the transistor and a second conductive region disposed in the transistor by using the second insulating film as a mask, the first and second conductive regions being spaced apart from each other; forming a first insulating film at least on the first conductive region, the first insulating film having a lower withstand voltage against dielectric breakdown than that of the second insulating film; forming a first electrode at least on the first insulating film; and forming a second electrode at least on the second insulating film.

In the manufacturing method of a semiconductor storage device in accordance with the second aspect of the present invention, the first insulating film having a lower withstand voltage against dielectric breakdown than that of the second insulating film, which is the gate insulating film of the transistor, can be formed in the state storage element. Therefore, it is possible to manufacture a semiconductor storage device in which data can be recorded in the state storage element by dielectrically breaking down the first insulating film by a lower writing voltage.

The present invention can provide a semiconductor storage device that satisfies both the data writing at a lower voltage and the higher packing density, and its manufacturing method.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross section showing a configuration of a semiconductor storage device in accordance with a first exemplary embodiment of the present invention;

FIG. 2A is a cross section showing a manufacturing process of a semiconductor storage device in accordance with a first exemplary embodiment of the present invention;

FIG. 2B is a cross section showing a manufacturing process of a semiconductor storage device in accordance with a first exemplary embodiment of the present invention;

FIG. 2C is a cross section showing a manufacturing process of a semiconductor storage device in accordance with a first exemplary embodiment of the present invention;

FIG. 2D is a cross section showing a manufacturing process of a semiconductor storage device in accordance with a first exemplary embodiment of the present invention;

FIG. 2E is a cross section showing a manufacturing process of a semiconductor storage device in accordance with a first exemplary embodiment of the present invention;

FIG. 3 is a circuit diagram showing a layout of a memory cell including a semiconductor storage device in accordance with a first exemplary embodiment of the present invention;

FIG. 4 is a cross section taken along the line IV-IV in FIG. 3, showing a sectional structure;

FIG. 5 is a circuit diagram showing a layout of a memory cell including a semiconductor storage device in accordance with a first exemplary embodiment of the present invention;

FIG. 6 is a cross section taken along the line VI-VI in FIG. 5, showing a sectional structure;

FIG. 7 is a cross section showing a configuration of a semiconductor storage device in accordance with a second exemplary embodiment of the present invention;

FIG. 8A is an enlarged cross section showing a manufacturing process of a semiconductor storage device in accordance with a second exemplary embodiment of the present invention;

FIG. 8B is an enlarged cross section showing a manufacturing process of a semiconductor storage device in accordance with a second exemplary embodiment of the present invention;

FIG. 8C is an enlarged cross section showing a manufacturing process of a semiconductor storage device in accordance with a second exemplary embodiment of the present invention;

FIG. 8D is an enlarged cross section showing a manufacturing process of a semiconductor storage device in accordance with a second exemplary embodiment of the present invention;

FIG. 8E is an enlarged cross section showing a manufacturing process of a semiconductor storage device in accordance with a second exemplary embodiment of the present invention;

FIG. 8F is an enlarged cross section showing a manufacturing process of a semiconductor storage device in accordance with a second exemplary embodiment of the present invention;

FIG. 8G is an enlarged cross section showing a manufacturing process of a semiconductor storage device in accordance with a second exemplary embodiment of the present invention;

FIG. 8H is an enlarged cross section showing a manufacturing process of a semiconductor storage device in accordance with a second exemplary embodiment of the present invention;

FIG. 8I is an enlarged cross section showing a manufacturing process of a semiconductor storage device in accordance with a second exemplary embodiment of the present invention;

FIG. 8J is an enlarged cross section showing a manufacturing process of a semiconductor storage device in accordance with a second exemplary embodiment of the present invention;

FIG. 8K is an enlarged cross section showing a manufacturing process of a semiconductor storage device in accordance with a second exemplary embodiment of the present invention;

FIG. 8L is an enlarged cross section showing a manufacturing process of a semiconductor storage device in accordance with a second exemplary embodiment of the present invention;

FIG. 8M is an enlarged cross section showing a manufacturing process of a semiconductor storage device in accordance with a second exemplary embodiment of the present invention;

FIG. 8N is an enlarged cross section showing a manufacturing process of a semiconductor storage device in accordance with a second exemplary embodiment of the present invention;

FIG. 8O is an enlarged cross section showing a manufacturing process of a semiconductor storage device in accordance with a second exemplary embodiment of the present invention;

FIG. 8P is an enlarged cross section showing a manufacturing process of a semiconductor storage device in accordance with a second exemplary embodiment of the present invention;

FIG. 9 is a cross section showing a configuration of a semiconductor storage device in accordance with a third exemplary embodiment of the present invention;

FIG. 10A is an enlarged cross section showing a manufacturing process of a semiconductor storage device in accordance with a third exemplary embodiment of the present invention;

FIG. 10B is an enlarged cross section showing a manufacturing process of a semiconductor storage device in accordance with a third exemplary embodiment of the present invention;

FIG. 10C is an enlarged cross section showing a manufacturing process of a semiconductor storage device in accordance with a third exemplary embodiment of the present invention;

FIG. 10D is an enlarged cross section showing a manufacturing process of a semiconductor storage device in accordance with a third exemplary embodiment of the present invention;

FIG. 10E is an enlarged cross section showing a manufacturing process of a semiconductor storage device in accordance with a third exemplary embodiment of the present invention;

FIG. 11 is a cross section showing a configuration of a memory cell disclosed in Published Japanese Translation of PCT International Publication for Patent Application, No. 2005-504434;

FIG. 12 is a cross section showing a configuration of a memory portion of an anti-fuse transistor disclosed in Published Japanese Translation of PCT International Publication for Patent Application, No. 2007-536744;

FIG. 13A is a cross section showing a typical manufacturing process of an anti-fuse transistor disclosed in Published Japanese Translation of PCT International Publication for Patent Application, No. 2007-536744;

FIG. 13B is a cross section showing a typical manufacturing process of an anti-fuse transistor disclosed in Published Japanese Translation of PCT International Publication for Patent Application, No. 2007-536744;

FIG. 13C is a cross section showing a typical manufacturing process of an anti-fuse transistor disclosed in Published Japanese Translation of PCT International Publication for Patent Application, No. 2007-536744:

FIG. 13D is a cross section showing a typical manufacturing process of an anti-fuse transistor disclosed in Published Japanese Translation of PCT International Publication for Patent Application, No. 2007-536744;

FIG. 13E is a cross section showing a typical manufacturing process of an anti-fuse transistor disclosed in Published Japanese Translation of PCT International Publication for Patent Application, No. 2007-536744; and

FIG. 13F is a cross section showing a typical manufacturing process of an anti-fuse transistor disclosed in Published Japanese Translation of PCT International Publication for Patent Application, No. 2007-536744.

### DETAILED DESCRIPTION OF THE EXEMPLARY EMBODIMENTS

### First Exemplary Embodiment

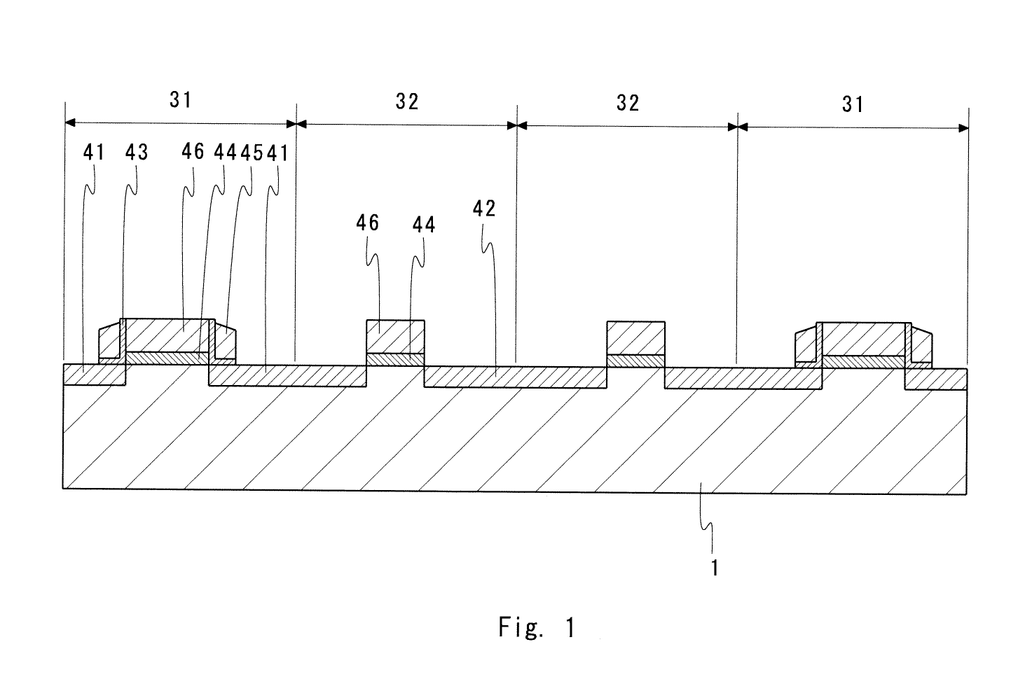

A first exemplary embodiment of the present invention is explained hereinafter with reference to the drawings. Firstly, a configuration of a semiconductor storage device in accordance with this exemplary embodiment is explained. FIG. 1 is a cross section showing a configuration of a semiconductor storage device in accordance with the first exemplary embodiment. As shown in FIG. 1, this semiconductor storage device includes a state storage element 31 in which data is recorded, and a transistor 32 which is a MOS (Metal Oxide Semiconductor) type transistor.

In this semiconductor storage device, a first conductive region 41 and a second conductive region 42 are formed in a semiconductor substrate 1. The semiconductor substrate 1 is composed of, for example, p-type silicon. The first and second conductive regions 41 and 42 are composed of, for example, an n-type impurity diffusion layer.

In the state storage element 31, a first insulating film 43 is formed in such a manner that it is in contact with at least a part of the first conductive region 41. The first insulating film 43 is composed of, for example, silicon oxide. A first conductive layer 45 is formed on the first insulating film 43.

A second insulating film 44 is formed on the semiconductor substrate 1. A second electrode 46 is formed on the second insulating film 44. However, the second insulating film 44 and the second electrode 46 are left unremoved just because they are used as a mask layer when the first and second conductive regions 41 and 42 are formed. Therefore, the second insulating film 44 and the second electrode 46 may be removed at some step in the manufacturing process of the semiconductor storage device.

In the transistor 32, a first conductive region 41, which extends from the state storage element 31, is formed. Further, in the transistor 32, a second insulating film 44, for example, is formed on the channel layer (an area of the semiconductor substrate 1 located between the first and second conductive regions 41 and 42). A second electrode 46 is formed on the second insulating film 44. That is, the second insulating film 44 functions as a gate insulating film of the transistor 32. The second electrode 46 functions as a gate electrode of the transistor 32.

Note that the first insulating film 43 is composed of the same insulating material as the second insulating film 44. Further, the first and second insulating films 43 and 44 are formed with a small thickness. As a result, the first insulating film 43 has a lower dielectric breakdown voltage than that of the second insulating film 44. Therefore, it is possible to dielectrically break down the first insulating film 43 by a lower voltage than the voltage that is required to break down the second insulating film 44 in order to record data in the state storage element 31. Further, it is also possible to lower the withstand voltage against dielectric breakdown of the first insulating film 43, for example, by using material having a lower withstand voltage against dielectric breakdown than that of the second insulating film 44.

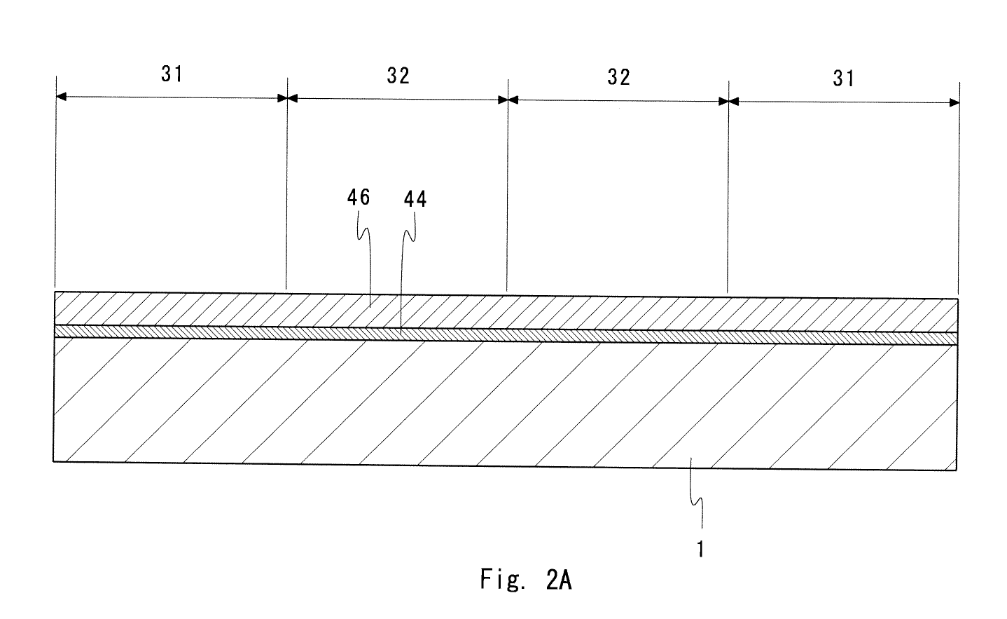

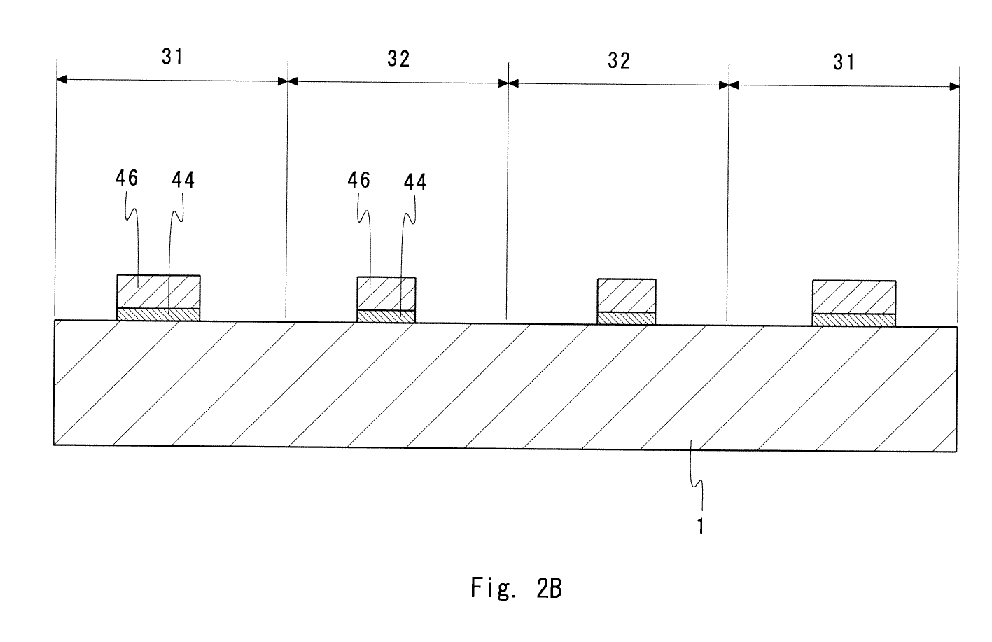

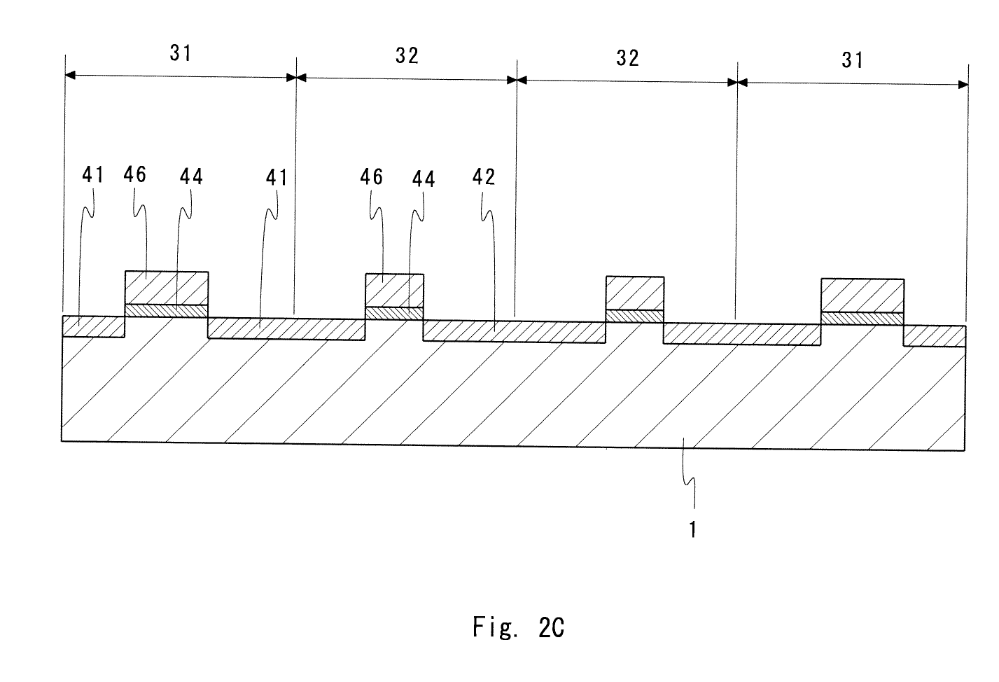

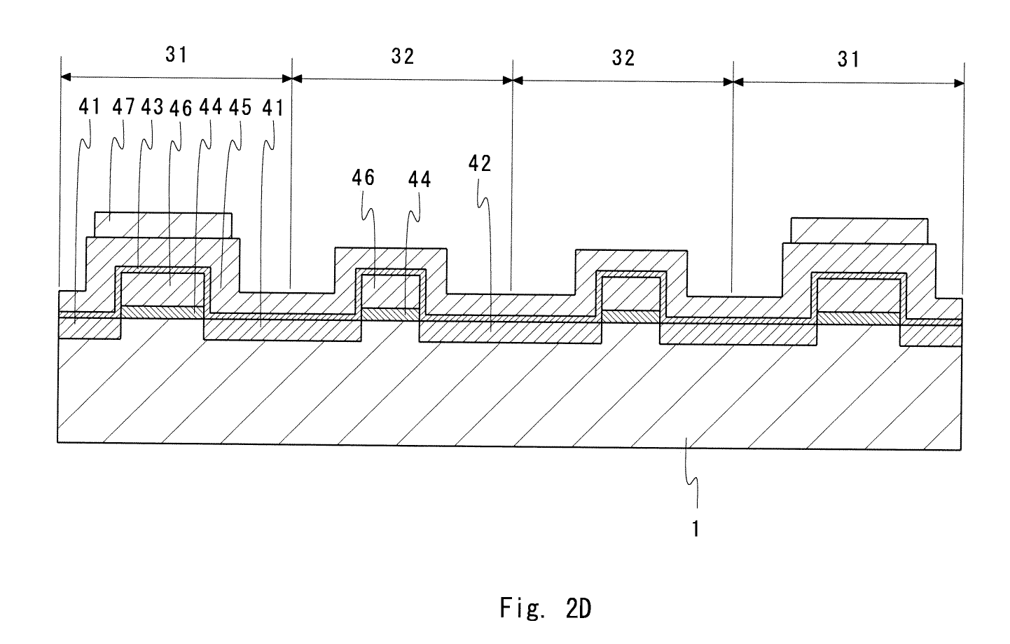

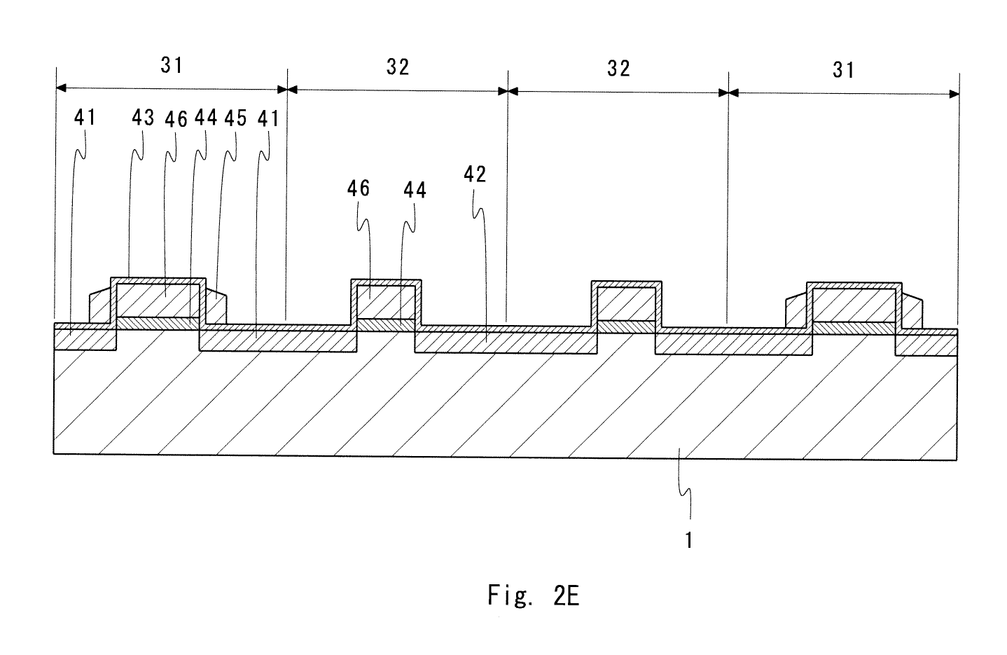

Next, a manufacturing method of this semiconductor storage device is explained. FIGS. 2A to 2E are cross sections showing a manufacturing process of the semiconductor storage device. Firstly, as shown in FIG. 2A, a second insulating film 44 and a second electrode 46 are successively deposited on a semiconductor substrate 1 by using, for example, a CVD (Chemical Vapor Deposition) method. Note that the semiconductor substrate 1 is composed of, for example, p-type silicon. The second insulating film 44 is composed of, for example, silicon oxide. The second electrode 46 is composed of, for example, polysilicon. Next, as shown in FIG. 2B, parts of the second insulating film 44 and the second electrode 46 are removed by, for example, photolithography and etching. Next, as shown in FIG. 2C, a first conductive region 41 and a second conductive region 42 are formed by ion implantation using the second insulating film 44 and the second electrode 46 as a mask. In this process, phosphorus ions, for example, are implanted so that an n-type first conductive region 41 and an n-type second conductive region 42 are formed.

Next, as shown in FIG. 2D, a first insulating film 43 and a first electrode 45 are deposited by using, for example, a CVD method. Note that the first insulating film 43 is composed of, for example, silicon oxide. The first electrode 45 is composed of, for example, polysilicon. In this process, the first insulating film 43 is deposited in a smaller thickness than that of the second insulating film 44, for example, so that the first insulating film 43 has a lower withstand voltage against dielectric breakdown than that of the second insulating film 44. Next, a first etching mask 47 is formed in the state storage element 31 by, for example, photolithography. Next, as shown in FIG. 2E, dry-etching such as RIE (Reactive Ion Etching), for example, is carried out by using the first etching mask 47 as a mask. In this way, the first electrode 45 is etched in such a manner that a part of the first electrode 45 is left unremoved in the state storage element 31. Finally, the first insulating film 43 is removed by carrying out dry-etching such as RIE, for example, using the first electrode 45 as a mask. As a result, the state storage element shown in FIG. 1 is manufactured.

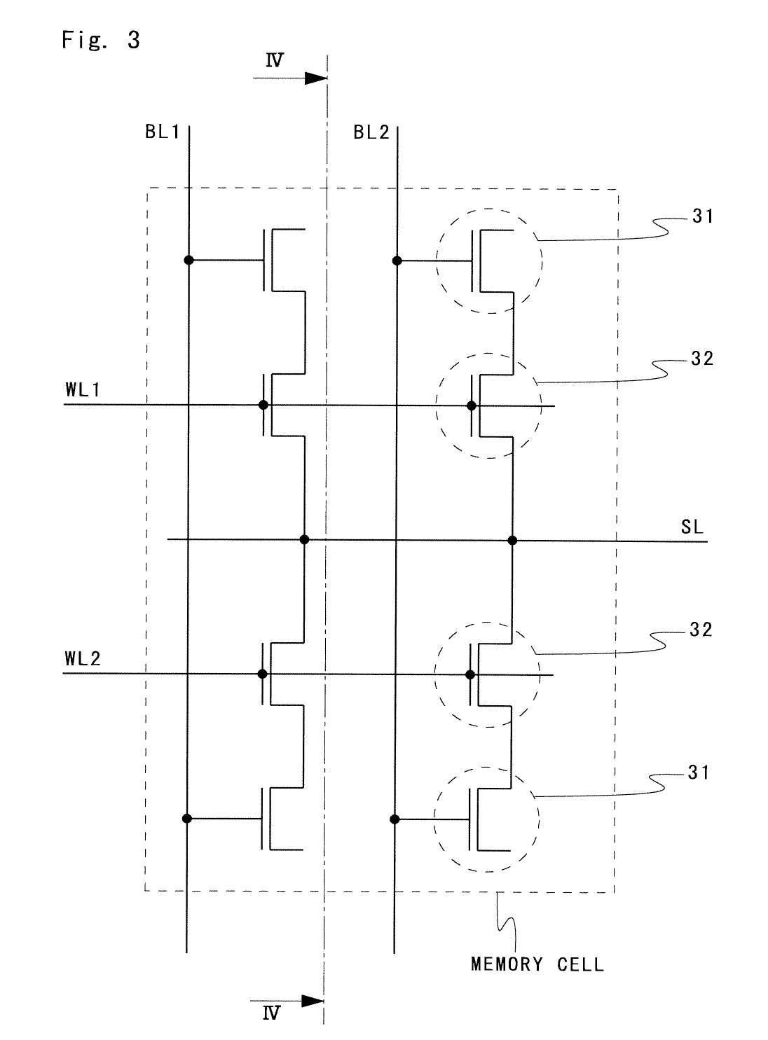

Next, an operation of this semiconductor storage device is explained. FIG. 3 is a circuit diagram showing a memory cell in which this semiconductor storage device is disposed. As shown in FIG. 3, word lines WL1 and WL2 are connected to the gates of transistors 32 in the memory cell. Bit lines BL1 and B12 are connected to the gates of half transistors, which serve as state storage elements 32. A supply line SL is connected to nodes between the transistors 32.

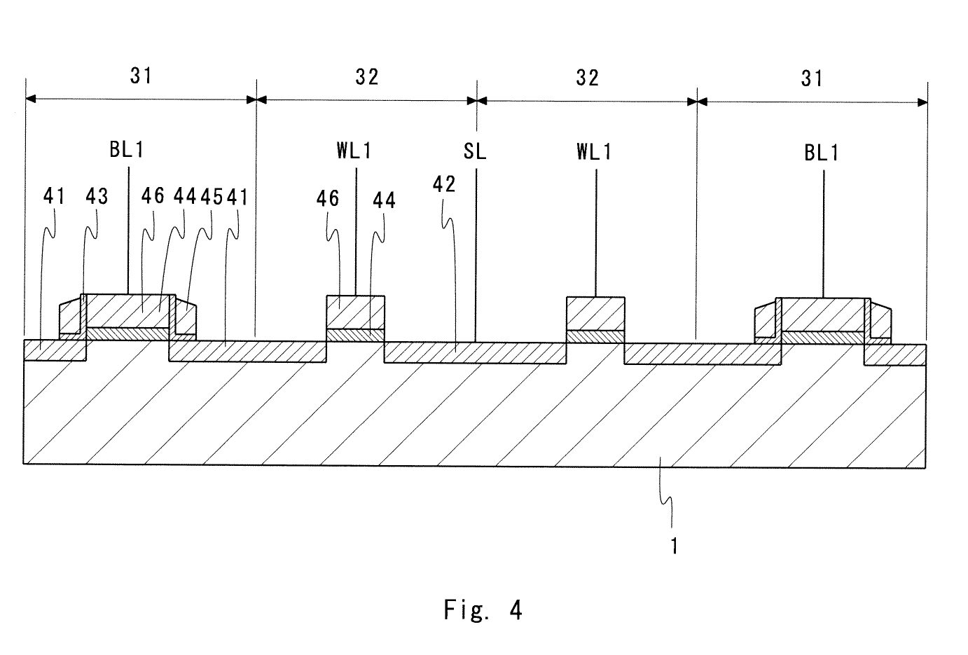

FIG. 4 is a cross section showing a sectional structure taken along the line IV-IV of FIG. 3. The components in FIG. 4 are denoted by the same signs as those in FIG. 1, and therefore their explanation is omitted. In this semiconductor storage device, data is written by dielectrically breaking down the first insulating film 43. To write data into this semiconductor storage device, the supply line SL is brought to a ground potential and the word line WL1 is brought to a High-level potential. By bringing the bit line BL1 to a High-level potential in this state, a voltage is applied to the first insulating film 43. As a result, the first insulating film 43 is dielectrically broken down and thereby becomes a conductive state.

To read data, the bit line BL1, the supply line SL, and the word line WL1 are used, for example, as a drain, a source, and a gate respectively. A current that flows from the source to the drain when: the supply line SL, which serves as the source, is brought to a ground potential; the word line WL1, which serves as the gate, is brought to a High-level potential; and the bit line BL1, which serves as the drain, is brought to a potential lower than the High-level potential, is monitored.

In this state, if the first insulating film 43 has been dielectrically broken down and thus in a conductive state, a current flows therethrough and it is recognized as a written state. On the other hand, if the first insulating film 43 has not been dielectrically broken down, no current flows and it is recognized as a non-written state.

In this semiconductor storage device, the first insulating film 43 is thinner than the second insulating film 44 and they are formed independently of each other. That is, since the first insulating film 43 can be formed with an arbitrary film-thickness, the first insulating film 43 can be dielectrically broken down by a desired voltage. Therefore, it is possible to write data at a lower voltage in comparison to the case where the gate insulating film of the transistor needs to be dielectrically broken down as in the case of the memory cell disclosed in Published Japanese Translation of PCT International Publication for Patent Application, No. 2005-504434.

Further, in accordance with the above-described manufacturing method, the distance between the state storage element 31 and the transistor 32 does not depend on the alignment accuracy of the device patterns, and is determined solely by the accuracy of the dimensions of the photomask. Therefore, it is unnecessary to take the redundancy required to compensate the alignment accuracy into consideration when the layout is designed, thus enabling the state storage element 31 and the transistor 32 to be arranged at the minimum interval. Accordingly, in accordance with the configuration and the manufacturing method described above, the recording density of the semiconductor storage device can be improved.

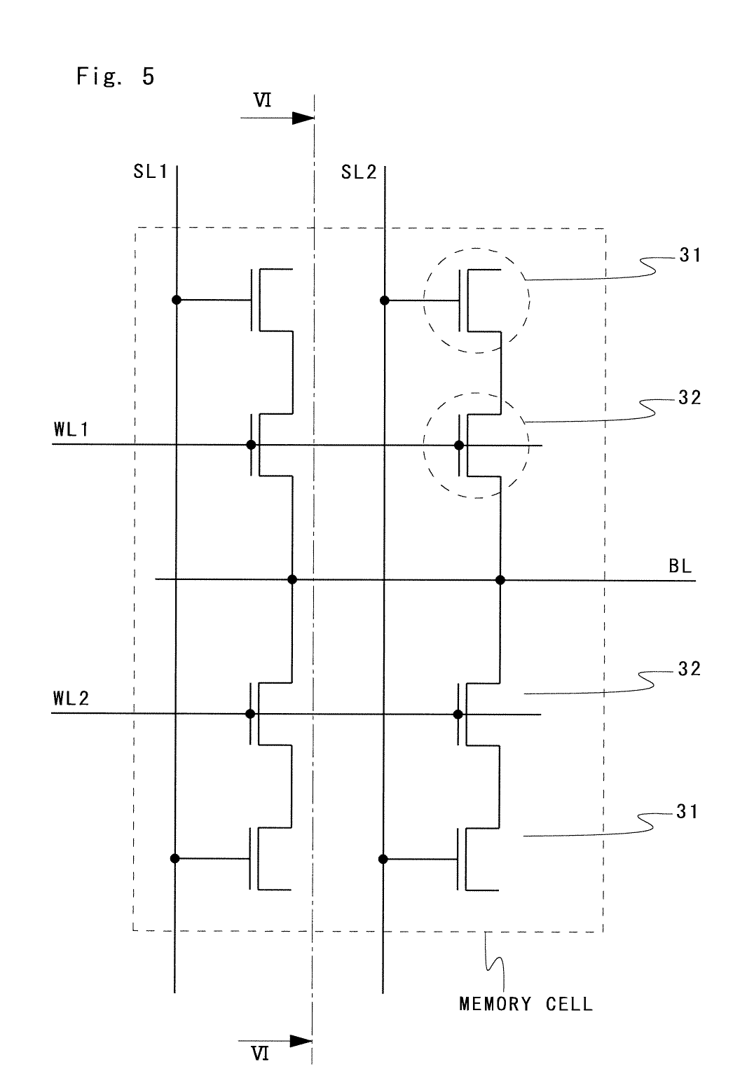

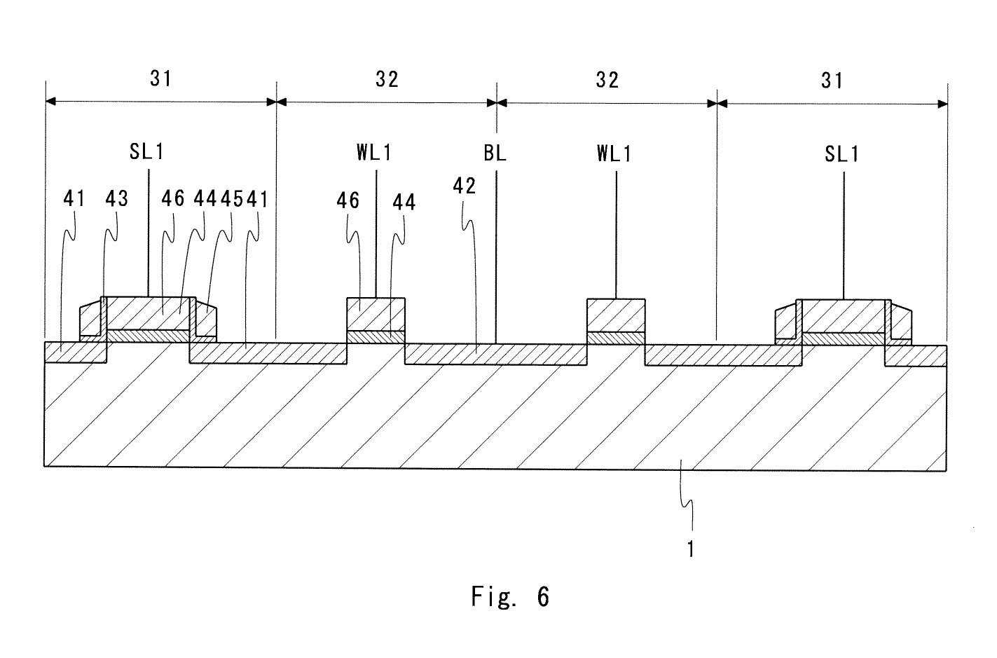

Note that in this semiconductor storage device, the supply line and the bit line in FIGS. 3 and 4, for example, can be interchanged with each other. FIG. 5 is a circuit diagram showing a layout of a memory cell in an example obtained by interchanging the supply line with the bit line in FIG. 3. FIG. 6 shows a cross section showing a sectional structure taken along the line VI-VI of FIG. 5. Even in the semiconductor storage device shown in FIG. 6, data writing and data reading can be performed in a similar manner to the example shown in FIG. 4.

### Second Exemplary Embodiment

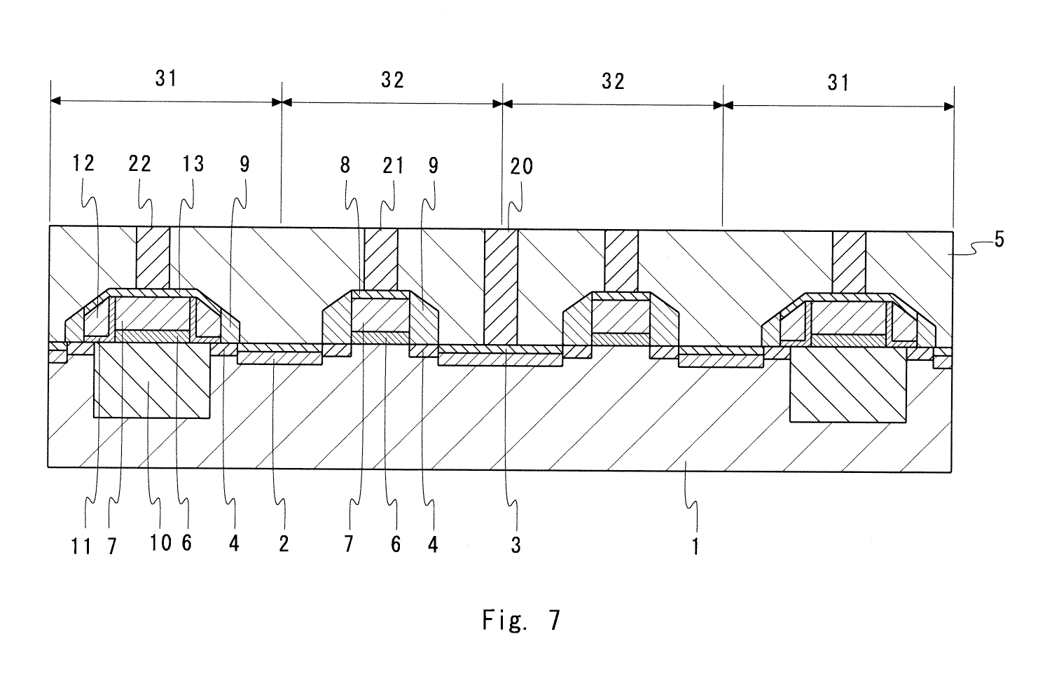

A semiconductor storage device in accordance with a second exemplary embodiment of the present invention is explained hereinafter. FIG. 7 is a cross section showing a configuration of a semiconductor storage device in accordance with the second exemplary embodiment of the present invention. As shown in FIG. 7, in this semiconductor storage device, a state storage element 31 in which data is recorded and a transistor 32 which is a MOS type transistor are formed on a semiconductor substrate 1. Note that the semiconductor substrate 1 is composed of, for example, p-type silicon. On the semiconductor substrate 1, a diffusion layer 2 and electrodes 3 are successively formed. The electrodes 3 are composed of, for example, silicide. Further, active layer extensions 4 are formed in such a manner that they are in contact with the diffusion layer 2 and the electrode 3. Further, this semiconductor storage device is covered with an interlayer insulating film 5. An opening is formed in a part of the interlayer insulating film 5 located above the electrode 3 sandwiched between the state storage elements 31, and the electrode 3 is led upward through a via 20.

In the transistor 32, a gate insulating film 6 is formed on an area of the semiconductor substrate 1 that is sandwiched between the active layer extensions 4. A conductive layer 7 is formed on the gate insulating film 6. An electrode 8 is formed on the conductive layer 7. Further, an insulating layer 9 is formed so as to cover the side of the gate insulating film 6, the conductive layer 7 and the electrode 8. An opening is formed in a part of the interlayer insulating film 5 located above the electrode 8, and the electrode 8 is led upward through a via 21. Note that the gate insulating film 6 is composed of, for example, silicon oxide. The conductive layer 7 is composed of, for example, polysilicon. The electrode 8 is composed of, for example, silicide. The insulating layer 9 is composed of, for example, silicon oxide.

In the state storage element 31, an element isolation region 10 that divides the active layer extension 4 is formed. In this example, the element isolation region 10 is formed as an STI (Shallow Trench Isolation). A gate insulating film 6 is formed on the element isolation region 10. A conductive layer 7 is formed on the gate insulating film 6.

Further, an insulating film 11 is formed so as to cover the upper surface of the active layer extension 4 and the element isolation region 10, and the side of the gate insulating film 6 and the conductive layer 7. The insulating film 11 is composed of, for example, silicon oxide. Note that the insulating film 11 is formed such that its withstand voltage against dielectric breakdown is lower than that of the gate insulating film 6. For example, the withstand voltage against dielectric breakdown of the insulating film 11 can be lowered by the combination of the insulating materials used for the gate insulating film 6 and the insulating film 11, or by forming the insulating film 11 with a smaller thickness than that of the gate insulating film 6. A conductive layer 12 is formed on the insulating film 11. The conductive layer 12 is composed of, for example, polysilicon.

Then, an electrode 13 is formed so as to cover the conductive layer 7, the insulating film 11, and the conductive layer 12. The electrode 13 is composed of, for example, silicide. An opening is formed in a part of the interlayer insulating film 5 located above the electrode 13, and the electrode 13 is led upward through a via 22. Further, an insulating layer 9 is formed so as to cover the side of the insulating film 11, the conductive layer 12, and the electrode 13.

In the semiconductor storage device in accordance with this exemplary embodiment, the active layer extension 4 formed between the state storage element 31 and the transistor 32 corresponds to the first conductive region 41 of FIG. 1. Further, in the transistor 32, the active layer extension 4 that is formed in the via 20 side corresponds to the second conductive region 42 of FIG. 1. Note that the diffusion layer 2 is formed so as to overlap the active layer extension 4. The active layer extension 4 and the diffusion layer 2, in combination, can have the same function as that of the first conductive region 41 and the second conductive region 42 of FIG. 1.

The insulating film 11 corresponds to the first insulating film 43 of FIG. 1 and the gate insulating film 6 corresponds to the second insulating film 44 of FIG. 1. Further, the electrode 13 and the electrode 8 correspond to the first electrode 45 and the second electrode 46, respectively, of FIG. 1. Further, it has such a configuration that the conductive layer 12 is added between the insulating film 11 and the electrode 13, and the conductive layer 7 is added between the gate insulating film 6 and the electrode 8.

Note that although the first and second conductive regions have two diffusion layers of the diffusion layer 2 and the active layer extension 4, they can be replaced by a single diffusion layer.

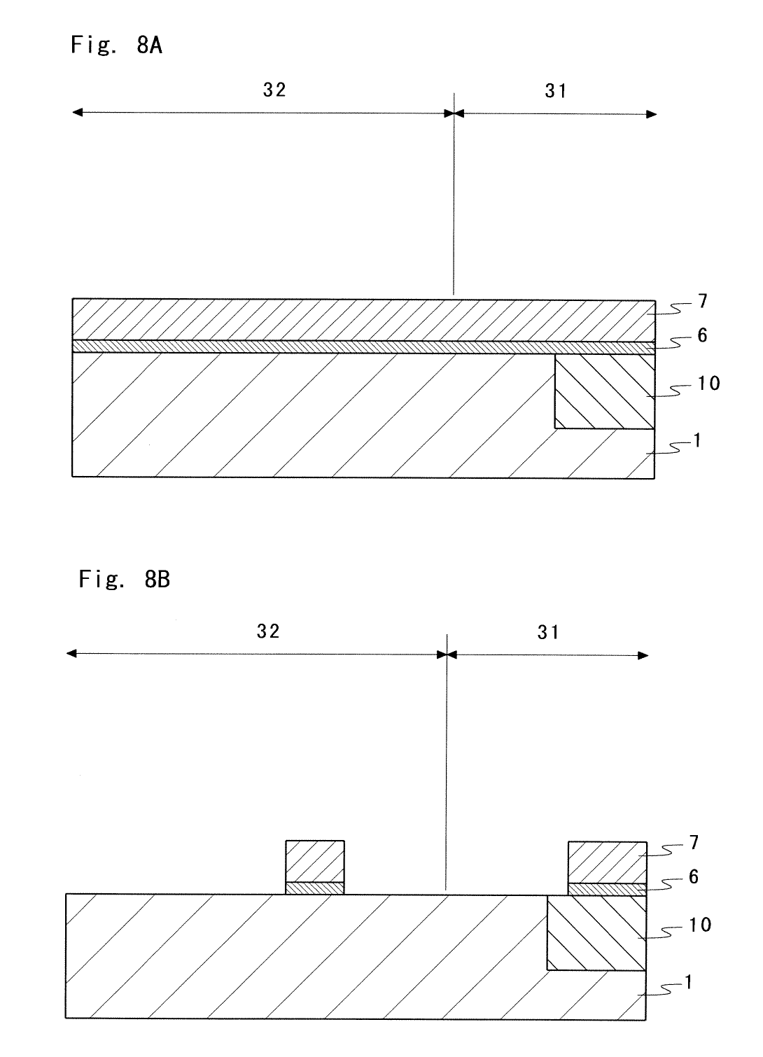

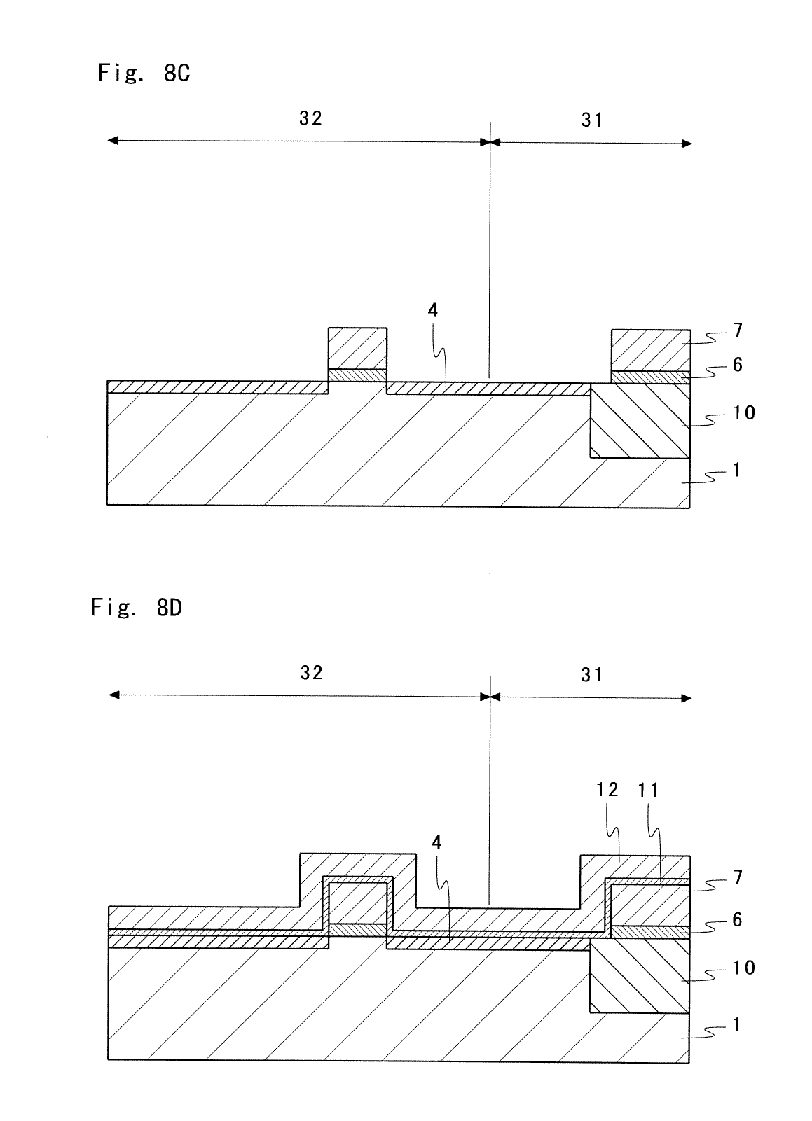

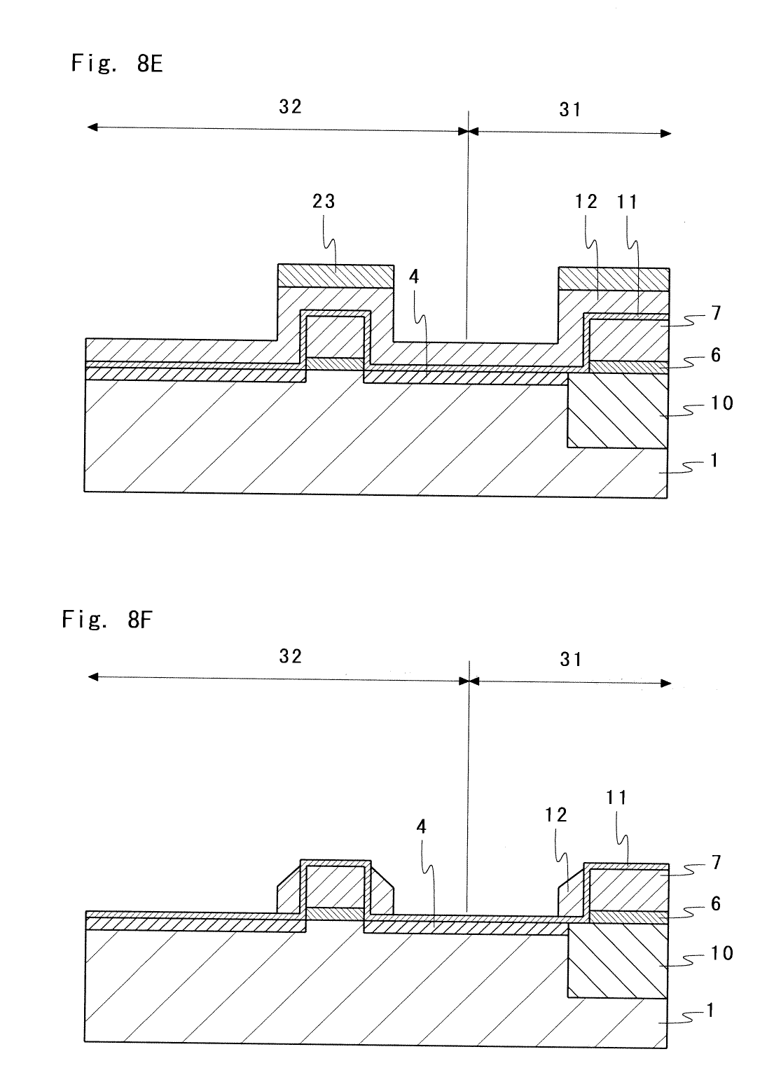

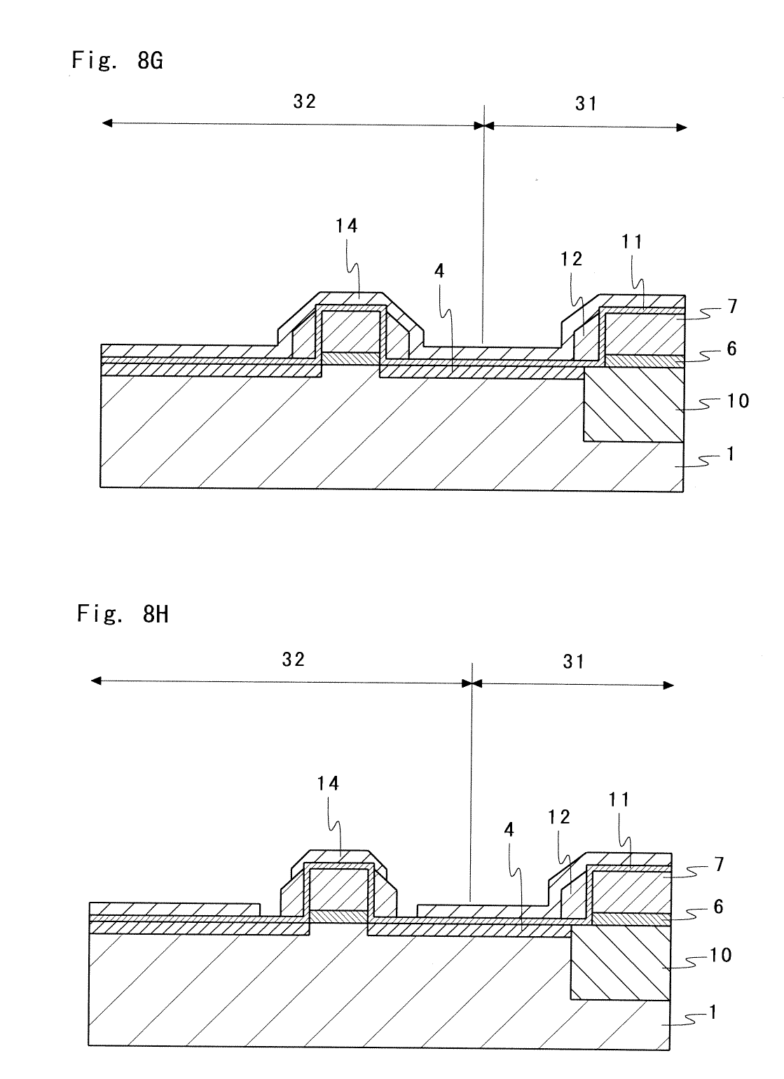

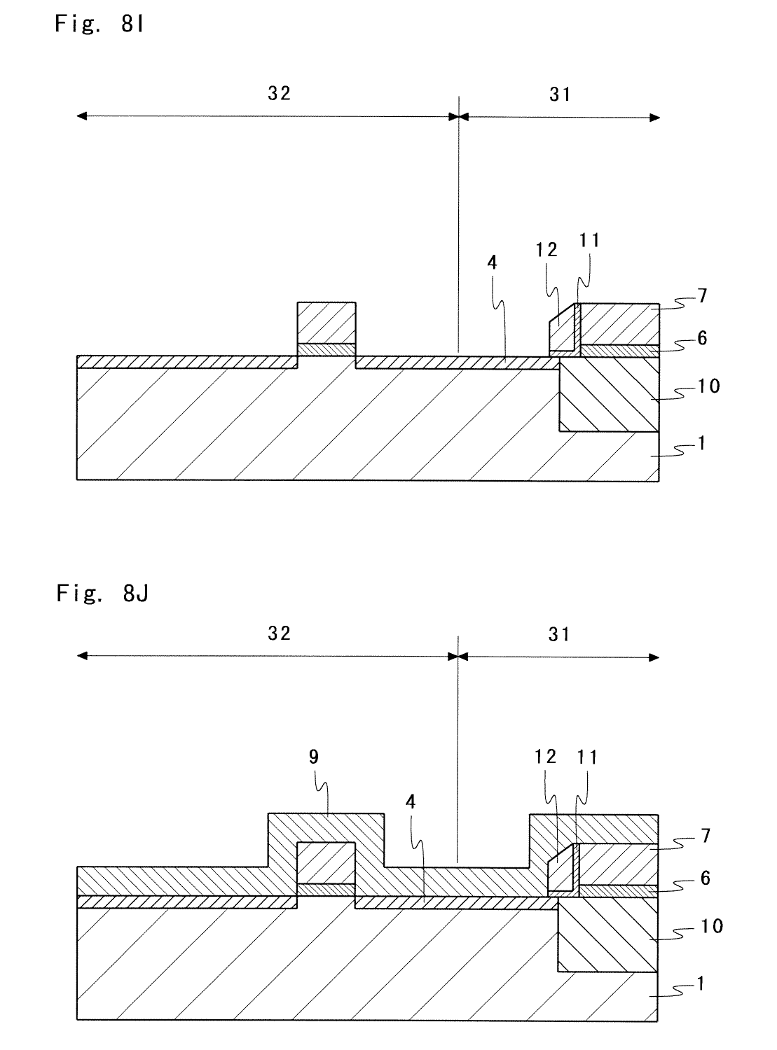

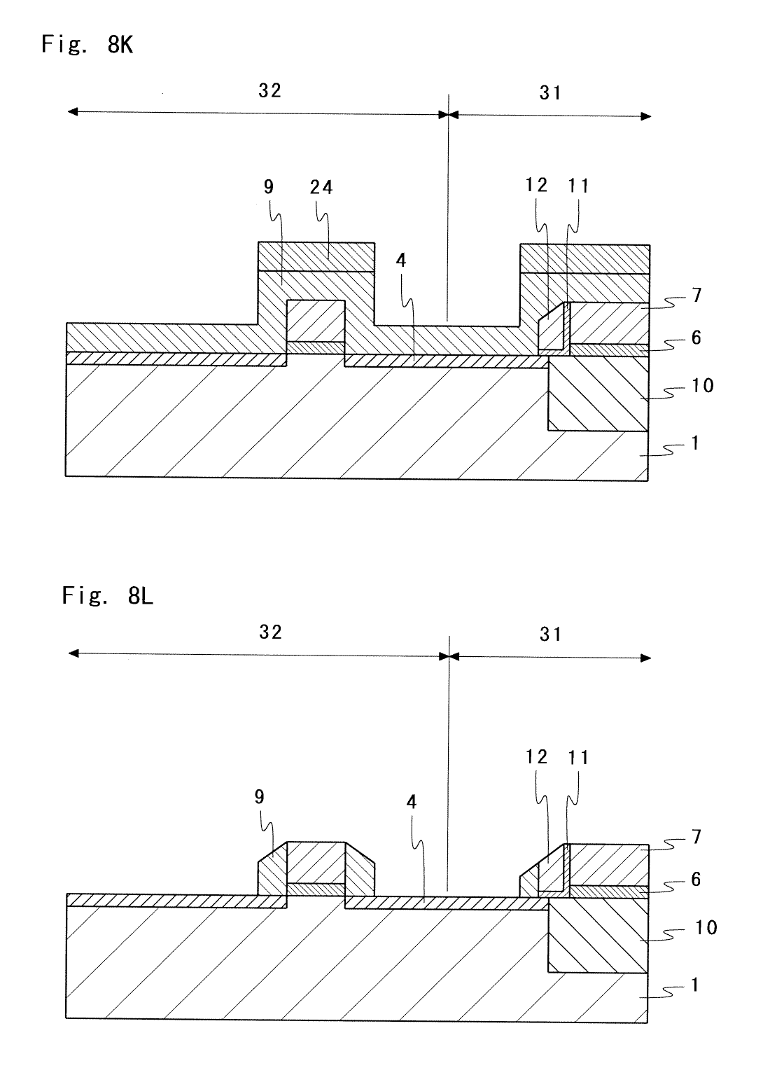

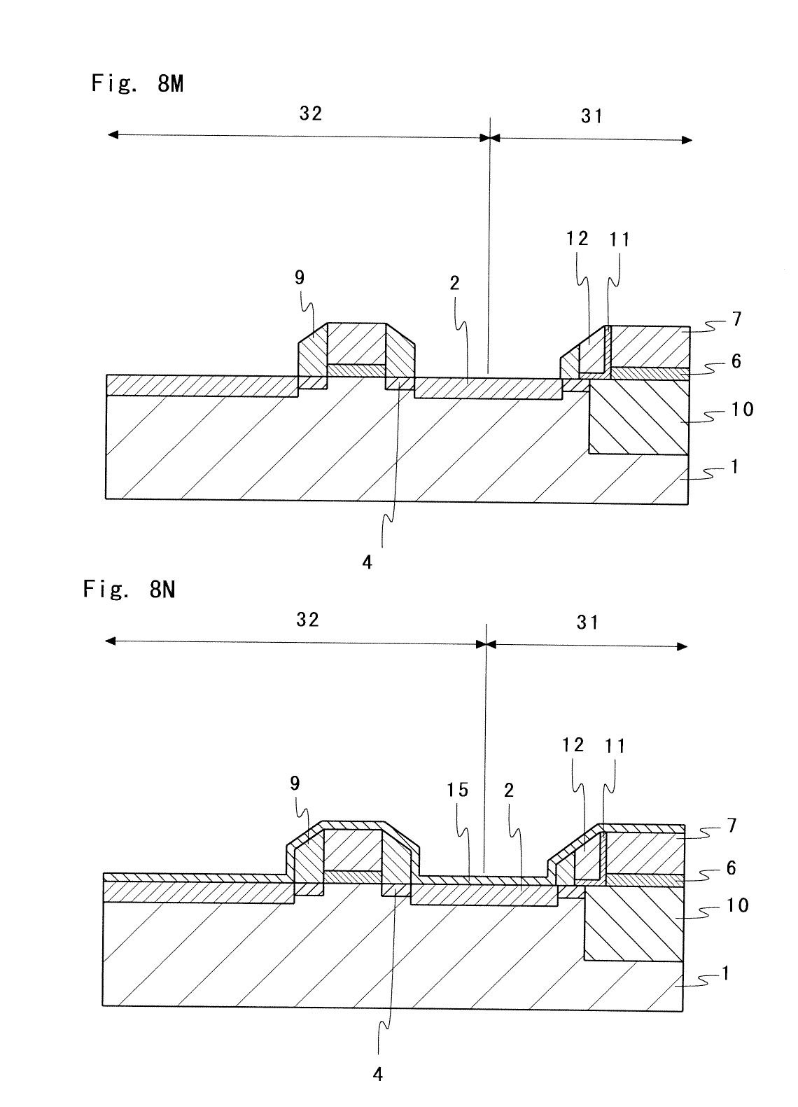

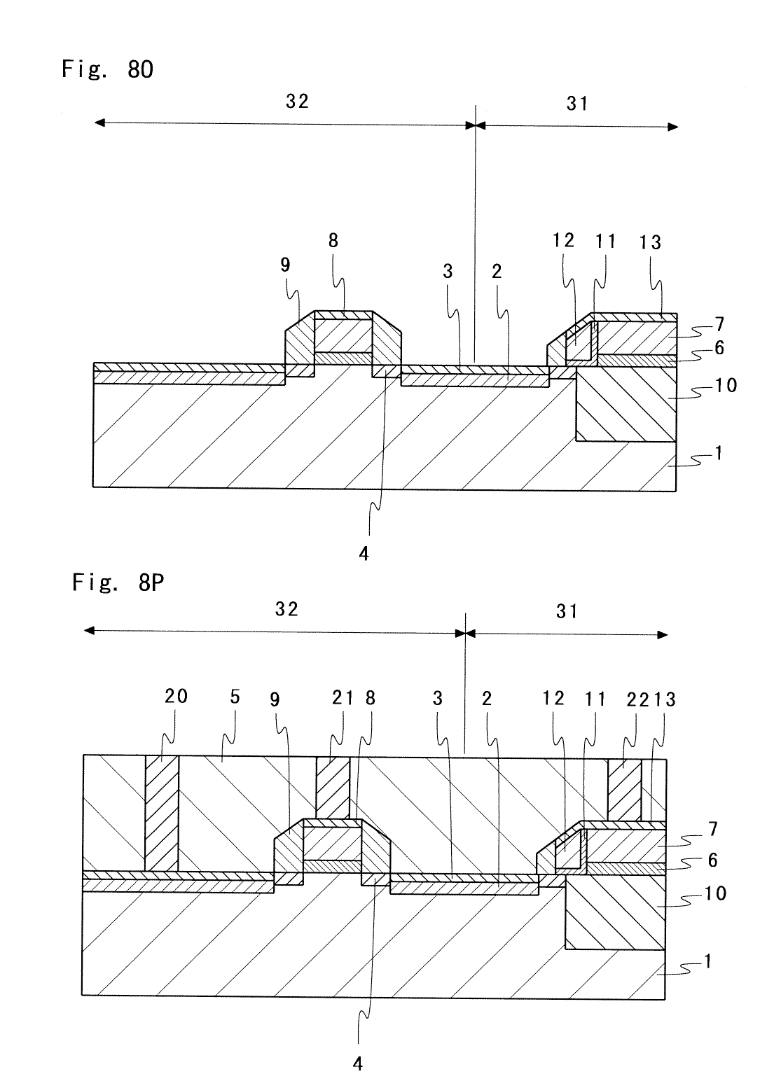

Next, a manufacturing method of this semiconductor storage device is explained. FIGS. 8A to 8E are enlarged cross sections showing a manufacturing process of this semiconductor storage device. As shown in FIG. 8A, an element isolation region 10 composed of an STI is formed on a semiconductor substrate 1. Next, a gate insulating film 6 and a conductive layer 7 composed of polysilicon are successively deposited over the semiconductor substrate 1 and the element isolation region 10 by using, for example, a CVD method. Note that the semiconductor substrate 1 is composed of, for example, p-type silicon. The gate insulating film 6 is composed of, for example, silicon oxide.

Next, a resist mask (not shown) is formed by, for example, photolithography. Next, as shown in FIG. 8B, parts of the gate insulating film 6 and the conductive layer 7 are removed by, for example, dry-etching such as RIE. Next, after the resist mask is removed, an active layer extension 4 is formed on the surface layer of the semiconductor substrate 1 by ion implantation as shown in FIG. 8C. In this process, phosphorus ions, for example, are implanted so that an n-type active layer extension 4 is formed.

Next, as shown in FIG. 8D, an insulating film 11 and a conductive layer 12 are formed so as to cover the state storage element 31 and the transistor 32. The insulating film 11 is composed of, for example, silicon oxide. The conductive layer 12 is composed of, for example, polysilicon. In this process, the insulating film 11 may be formed with a thickness smaller than that of the gate insulating film 6 so that the insulating film 11 can have a lower withstand voltage against dielectric breakdown than that of the gate insulating film 6. Alternatively, the insulating film 11 may be formed from insulating material that has a lower withstand voltage against dielectric breakdown than that of the insulating material used for the gate insulating film 6.

Next, as shown in FIG. 8E, a resist 23 is formed by, for example, photolithography. Note that the resist 23 corresponds to the first etching mask 47 of FIG. 2D.

Next, as shown FIG. 8E, dry-etching such as RIE, for example, is carried out by using the resist 23 as an etching mask to partially remove the conductive layer 12. After that, the resist 23 is removed.

Next, as shown FIG. 8G, an oxide film 14 is formed so as to cover the state storage element 31 and the transistor 32 by, for example, a CVD method. The oxide film 14 is composed of, for example, silicon oxide. Next, a resist mask (not shown) is formed by, for example, photolithography. Next, as shown FIG. 8H, dry-etching such as RIE, for example, is carried out to partially remove the oxide film 14. After that, the resist mask is removed.

Next, as shown FIG. 8I, the conductive layer 12 of the transistor 32 is selectively removed by wet-etching using, for example, a solution containing sulfuric acid. Next, the insulating film 11 and the oxide film 14 are selectively removed by wet-etching using, for example, buffered hydrogen fluoride. In this process, the wet-etching is carried out in such a manner that the insulating film 11 of the state storage element 31 is left unremoved. Note that the etchant used for the wet-etching of the conductive layer 12 composed of polysilicon is not limited to the solution containing sulfuric acid, and other etchants that can etch polysilicon may be also used. Further, the etchant used for the wet-etching of the insulating film 11 and the oxide film 14 is not limited to the buffered hydrogen fluoride, and other etchants that can etch an oxide film, such as hydrogen fluoride and an ammonium fluoride aqueous solution, may be also used.

Next, as shown FIG. 8J, an insulating layer 9 composed of silicon oxide is formed so as to cover the state storage element 31 and the transistor 32 by, for example, a CVD method. Next, as shown FIG. 8K, a resist 24, which serves as the second etching mask, is formed by, for example, photolithography. Next, as shown FIG. 8L, dry-etching such as RIE, for example, is carried out by using the resist 24 as an etching mask to partially remove the insulating layer 9. After that, the resist 24 is removed.

Next, as shown FIG. 8M, a diffusion layer 2 is formed by ion implantation. In this process, phosphorus ions, for example, are implanted so that an n-type diffusion layer 2 is formed. Next, as shown FIG. 8N, a metal layer 15 is formed so as to cover the state storage element 31 and the transistor 32. The metal layer 15 is composed of, for example, cobalt. Then, the surface layer of the diffusion layer 2 and the conductive layer 7 is converted into silicide by heat treatment. After that, as shown in FIG. 8O, the remaining metal layer 15 is removed by, for example, wet-etching to form the electrodes 3, 8 and 13.

Finally, as shown in FIG. 8P, an interlayer insulating film 5 is formed. The interlayer insulating film 5 is composed of, for example, polyimide. After that, openings are formed in parts of the interlayer insulating film 5 so that the electrodes 3, 8 and 13 are led upward through vias 20, 21 and 22 respectively. Each of the vias 20, 21 and 22 is formed, for example, by filling the opening with conductive material such as copper. Through the processes described above with reference to FIGS. 8A to 8P, the semiconductor storage device shown in FIG. 7 is manufactured.

In this semiconductor storage device, the insulating film 11 is thinner than the gate insulating film 6 and they are formed independently of each other. That is, data can be written at a low voltage as with the first exemplary embodiment.

Further, in accordance with the above-described manufacturing method, the distance between the state storage element 31 and the transistor 32 does not depend on the alignment accuracy of the device patterns, and is determined by the accuracy of the dimensions of the resist 24, which serves as the second mask. Therefore, the recording density of the semiconductor storage device can be improved as with the first exemplary embodiment.

Further, the electric field is concentrated, in particular, at the corner portion of the element isolation region 10. That is, the dielectric breakdown can be easily caused at an area where the insulating film 11 is in contact with the corner portion of the element isolation region 10. Therefore, in order to realize the writing at a low voltage, it is effective to dispose the corner portion of the element isolation region 10 in such a manner that it is in contact with the portion of the insulating film 11 where the dielectric breakdown should be caused.

### Third Exemplary Embodiment

A semiconductor storage device in accordance with a third exemplary embodiment of the present invention is different from that in accordance with the second exemplary embodiment in the structure of the side portion of the state storage element 31 and the transistor 32. With this structure, the semiconductor storage device can be manufactured by smaller number of processes and thus is more advantageous in terms of the cost reduction in comparison to that of the second exemplary embodiment.

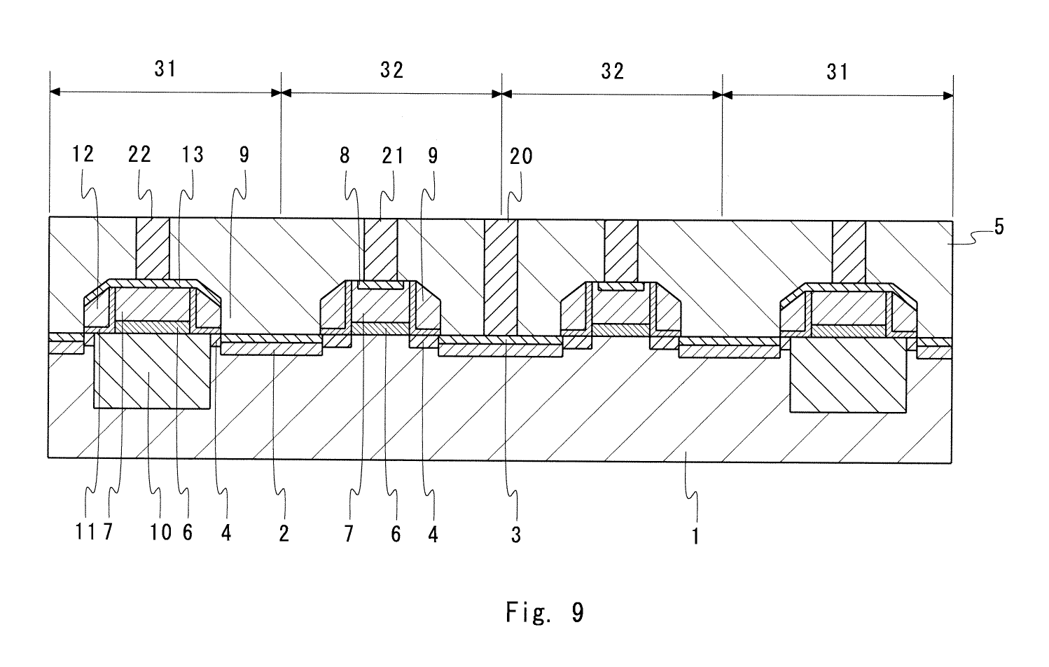

Firstly, a configuration of a semiconductor storage device in accordance with this exemplary embodiment is explained. FIG. 9 is a cross section showing a configuration of a semiconductor storage device in accordance with the third exemplary embodiment of the present invention. In the following explanation, only the differences from FIG. 7 are explained for simplifying the explanation. In a transistor 32 in FIG. 9, the insulating layer 9 and the insulating film 11 in FIG. 7 are replaced by a conductive layer 12. In a state storage element 31 in FIG. 9, the insulating layer 9 is removed. The other configuration is similar to that shown in FIG. 7, and therefore its explanation is omitted.

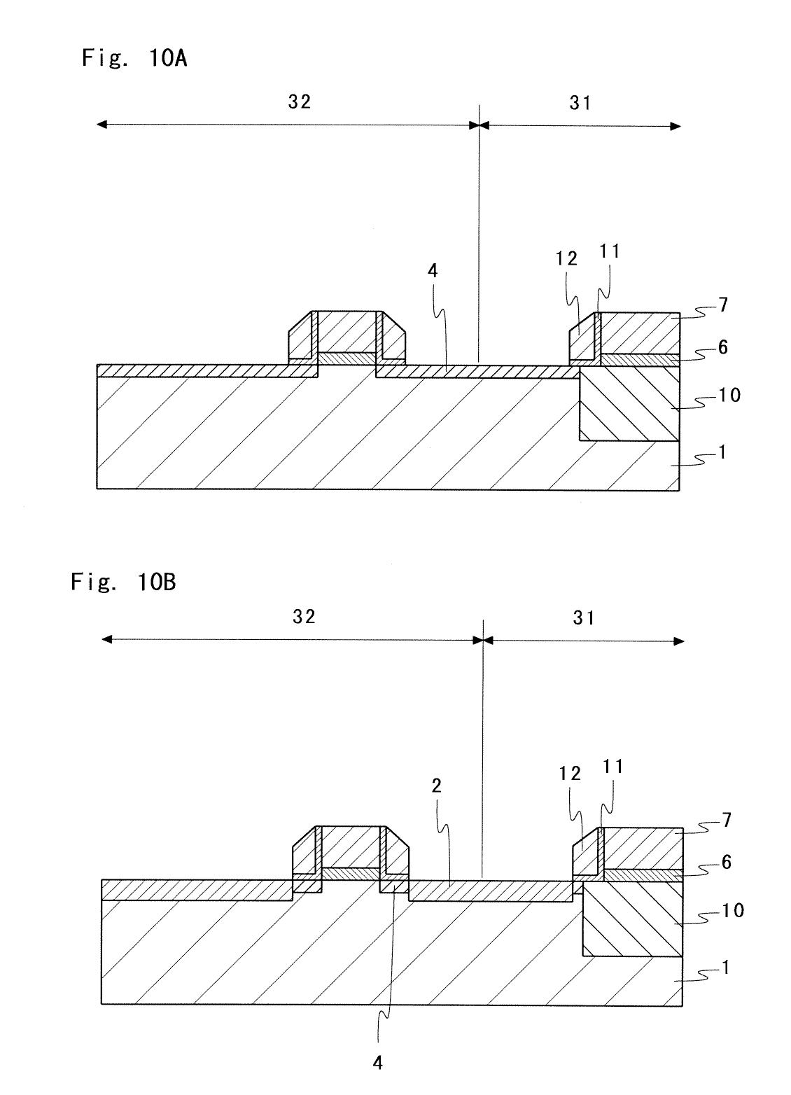

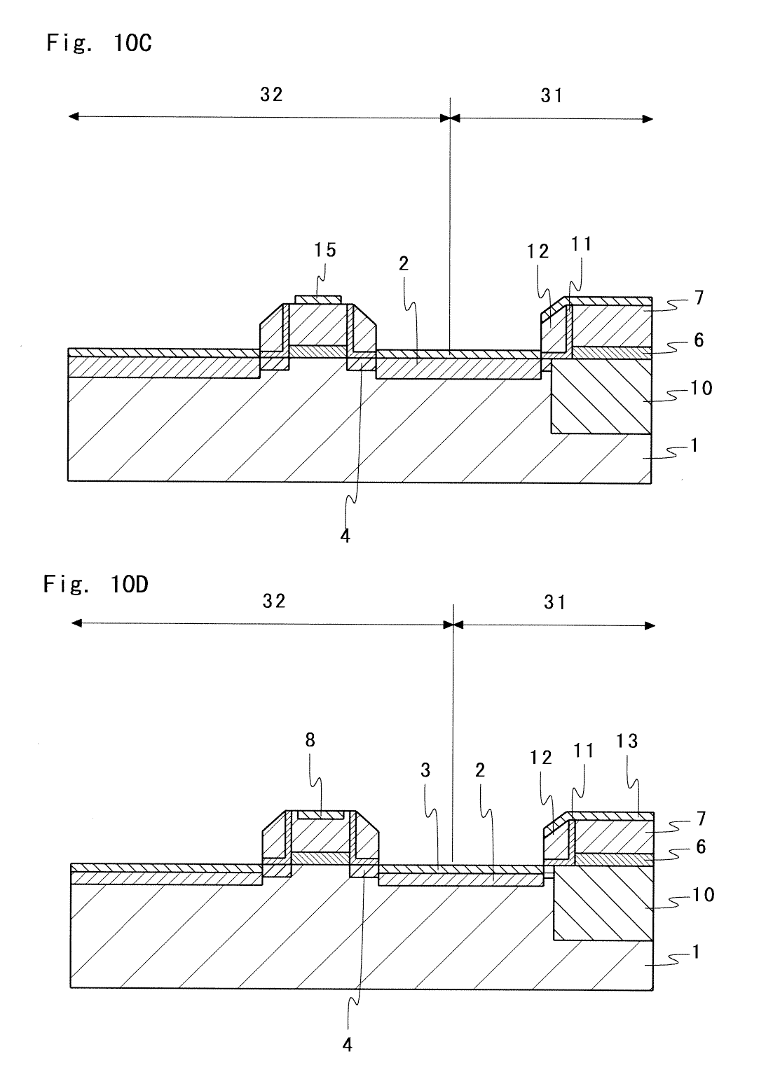

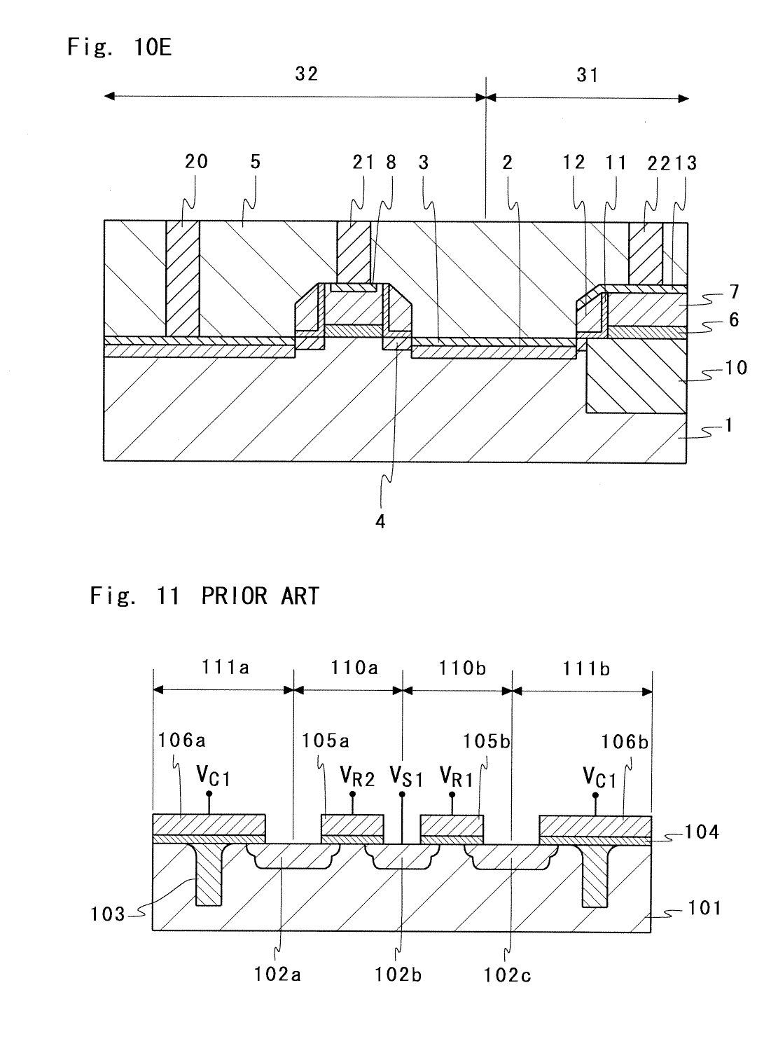

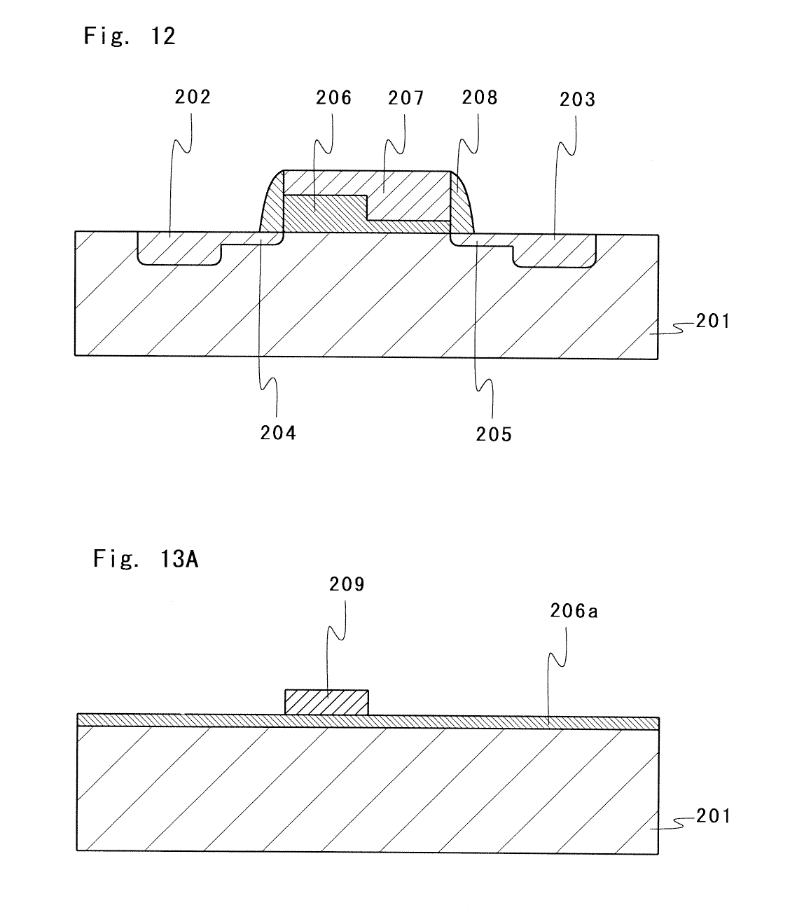

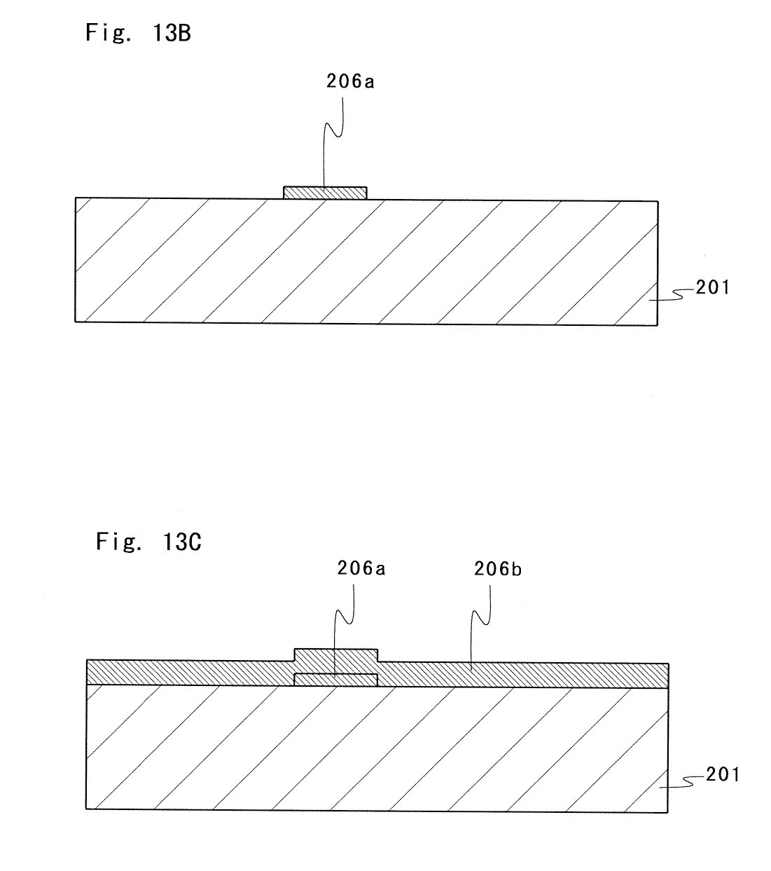

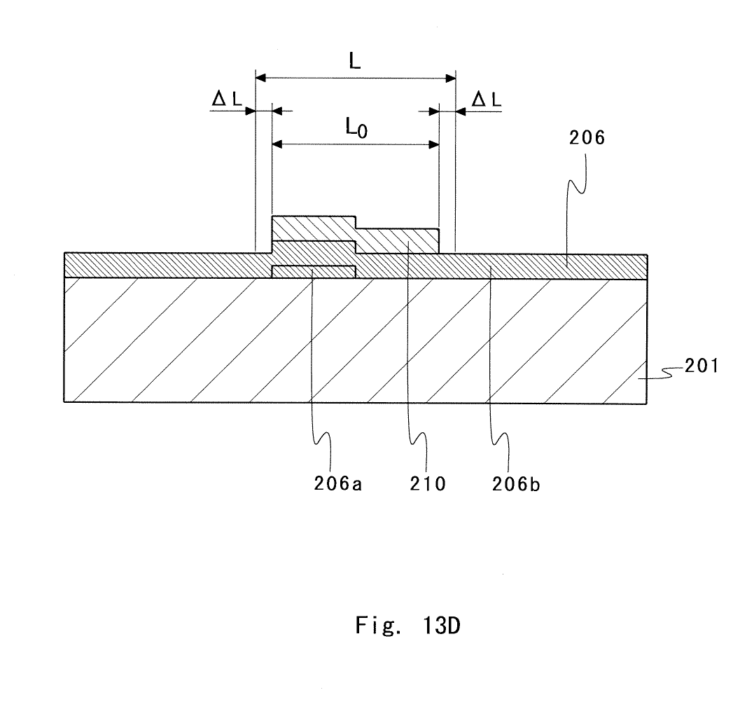

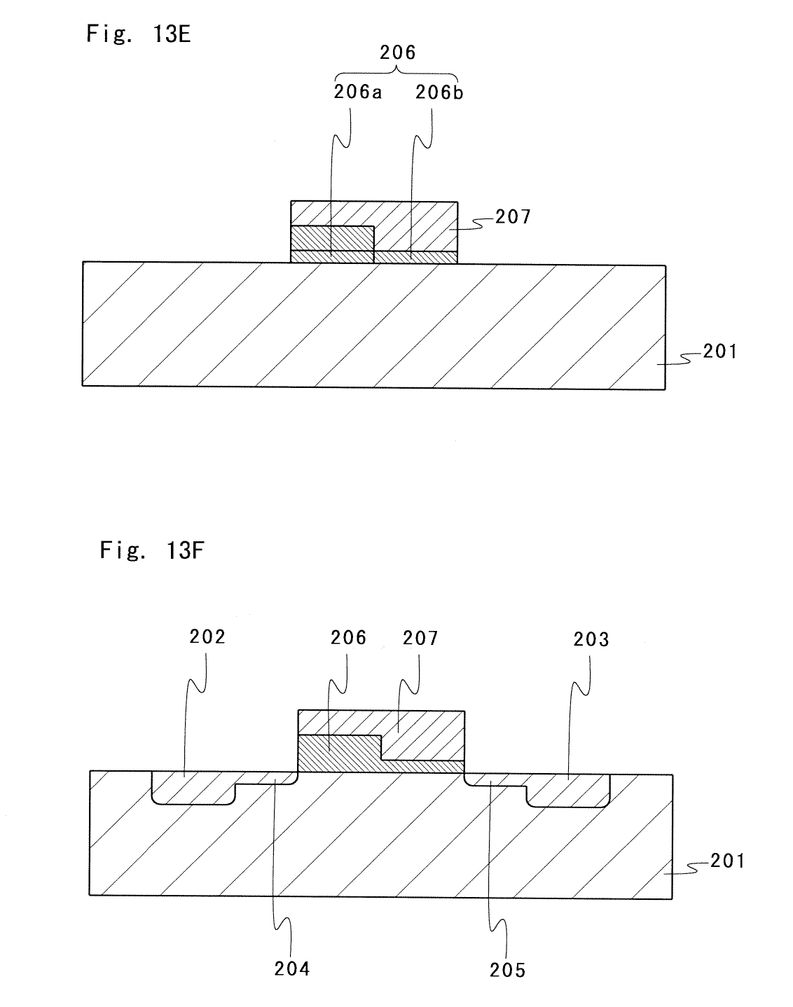

Next, a manufacturing method of this semiconductor storage device is explained. As for the manufacturing processes shown in FIGS. 8A to 8F, they are similar to those of the manufacturing method in accordance with the second exemplary embodiment, and therefore their explanation is omitted. FIGS. 10A to 10E are enlarged cross sections showing part of the manufacturing method of a semiconductor storage device in accordance with this exemplary embodiment that is carried out after FIG. 8F. After the process shown in FIG. 8E is finished, the insulating film 11 is partially removed, for example, by carrying out dry-etching such as RIE using the conductive layer 12 as a mask as shown in FIG. 10A. Next, as shown in FIG. 108, a diffusion layer 2 is formed by ion implantation. In this process, phosphorus ions, for example, are implanted so that an n-type diffusion layer 2 is formed. After that, a metal layer 15 is formed so as to cover the state storage element 31 and the transistor 32 (not shown). The metal layer 15 is composed of, for example, cobalt.

Next, a resist mask (not shown) is formed by, for example, photolithography. Next, as shown FIG. 10C, dry-etching, for example, is carried out to partially remove the metal layer 15. Next, as shown FIG. 10D, the metal layer 15 is converted into silicide by heat treatment to form electrodes 3, 8 and 13. Note that since the insulating film 11 is formed with a sufficiently small thickness, the conductive layer 7 and the conductive layer 12 of the state storage element 31 are electrically connected to each other through the electrode 13.

Finally, an interlayer insulating film 5 is formed as shown in FIG. 10E. The interlayer insulating film 5 is composed of, for example, polyimide. After that, openings are formed in parts of the interlayer insulating film 5 so that the electrodes 3, 8 and 13 are led upward through vias 20, 21 and 22 respectively. Each of the vias 20, 21 and 22 is formed, for example, by filling the opening with conductive material such as copper. Through the processes described above, the semiconductor storage device shown in FIG. 9 is manufactured.

In this semiconductor storage device, the insulating layer 9 in FIG. 7 is replaced by the insulating film 11 and the conductive layer 12 in the side portion of the transistor 32. However, the electrical conduction between the conductive layer 7 and the conductive layer 12 is prevented by the insulating film 11. Further, the insulating layer 9 shown in FIG. 7 does not exist in the side portion of the state storage element 31 of this semiconductor storage device. However, the insulating layer 9 does not have any effect on data writing in the state storage element 31. Therefore, the semiconductor storage device in accordance with the configuration described above can perform a similar operation to that of the semiconductor storage device shown in FIG. 7. That is, it is possible to perform writing at a low voltage and to improve the recording density.

Further, in accordance with the configuration and the manufacturing method described above, the formation process of the insulating layer 9 shown in FIG. 7 is unnecessary and therefore the manufacturing process can be shortened in comparison to the second exemplary embodiment. Therefore, it is more advantageous in terms of the cost reduction.

Further, the supply line and the bit line can be interchanged with each other as appropriate as in the case of the first exemplary embodiment.

### Other Exemplary Embodiments

Note that the present invention is not limited to the above-described exemplary embodiments, and various modifications can be made as appropriate without departing from the spirit and scope of the present invention. For example, needless to say, even when the conductive types of the semiconductor are interchanged, a semiconductor storage device having similar functions can be implemented.

Further, the semiconductor used for the substrate is not limited silicon. For example, other compound semiconductor material such as gallium arsenide, gallium nitride, and silicon carbide can be also used.

As for the insulating film and the insulating layer, they are also not limited to the silicon oxide. For example, other insulating material such as silicon oxynitride can be also used.

The impurity that is implanted by the ion implantation is not limited to phosphorus. For example, other n-type impurities such as arsenic can be also used.

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor storage device comprising:
a state storage element; and
a transistor, wherein
the state storage element comprises:
a semiconductor substrate;
a first conductive region formed on the semiconductor substrate;
a first insulating film formed at least above the first conductive region;
a second insulating film formed on the semiconductor substrate; and
a first electrode formed at least above the first insulating film, and
a transistor comprises:
the first conductive region formed on the semiconductor substrate, the first conductive region extending from the state storage element;
a second conductive region formed on the semiconductor substrate, the second conductive region being spaced apart from the first conductive region;
a second insulating film formed between the first and second conducting regions on the semiconductor substrate, the second insulating film being in common with the state storage element; and
a second electrode formed at least above the second insulating film, and
the first insulating film has a lower withstand voltage against dielectric breakdown than that of the second insulating film.

2. The semiconductor storage device according to claim 1, wherein the state storage element further comprises a conductive layer formed between the first insulating film and the first electrode.

3. The semiconductor storage device according to claim 1, wherein the first insulating film is formed from same insulating material as the second insulating film, and is thinner than the second insulating film.

4. The semiconductor storage device according to claim 1, wherein the first insulating film is formed from insulating material having a lower withstand voltage against dielectric breakdown than that of the second insulating film.

5. The semiconductor storage device according to claim 2, wherein the conductive layer is formed from polysilicon.

6. The semiconductor storage device according to claim 1, wherein the state storage element further comprises an element isolation region formed on the semiconductor substrate such that the element isolation region is in contact with the first insulating film and the first conductive region.

7. The semiconductor storage device according to claim 6, wherein the element isolation region is formed from insulative material filled in a trench formed in the semiconductor substrate.

8. The semiconductor storage device according to claim 1, wherein
a bit line is connected to the first electrode,
a word line is connected to the second electrode, and
a supply line is connected to the second conductive region.

9. The semiconductor storage device according to claim 1, wherein
a supply line is connected to the first electrode,
a word line is connected to the second electrode, and
a bit line is connected to the second conductive region.

10. A method of manufacturing a semiconductor storage device in which a state storage element that records data and a transistor that reads out data recorded in the state storage element are integrated on a semiconductor substrate, the manufacturing method comprising:
forming a second insulating film on a region of the semiconductor substrate at which the transistor is disposed and a region of the semiconductor substrate at which the state storage element is disposed;
forming a first conductive region extending from the state storage element to the transistor and a second conductive region disposed in the transistor by using the second insulating film as a mask, the first and second conductive regions being spaced apart from each other;
forming a first insulating film at least on the first conductive region, the first insulating film having a lower withstand voltage against dielectric breakdown than that of the second insulating film;
forming a first electrode at least on the first insulating film; and
forming a second electrode at least on the second insulating film.

11. The method of manufacturing a semiconductor storage device according to claim 10, further comprising:
depositing a first insulating film so as to cover the state storage element and the transistor;
depositing a conductive layer over the first insulating film;
forming a first etching mask on the conductive layer, the first etching mask having an opening formed at least above the first conductive region;
partially removing the conductive layer by using the first etching mask;
forming the first insulating film on the first conductive region by partially removing the first insulating film using a remaining portion of the conductive layer as a mask; and
forming the first electrode over the first insulating film by forming the first electrode on the conductive layer.

12. The method of manufacturing a semiconductor storage device according to claim 11, further comprising, when the first insulating film is to be formed on the first conductive region:
depositing an insulating layer so as to cover the state storage element and the transistor;
forming a second etching mask on the insulating layer, the second etching mask having an opening formed at least above the first conductive region; and
partially removing the insulating layer by using the second etching mask.
